(19) United States
(12) Patent Application Publication
(10) Pub. No.: US 2010/0207106 A1
(43) Pub. Date: Aug. 19, 2010

(54) STRUCTURE FOR REPAIRING PIXEL OF ORGANIC LIGHT EMITTING DISPLAY DEVICE AND METHOD OF REPAIRING THE SAME

(76) Inventors: Zail Lhee, Yongin-city (KR); Sang-Mok Hong, Yongin-city (KR); Sun-Youl Lee, Yongin-city (KR)

Correspondence Address: CHRISTIE, PARKER & HALE, LLP, PO BOX 7068, PASADENA, CA, 91109-7068, US

(21) Appl. No.: 12/636,638

(22) Filed: Dec. 11, 2009

(30) Foreign Application Priority Data
Feb. 16, 2009 (KR) 10-2009-0012311

(51) Int. Cl. H01L 51/52; H01L 51/56

(52) U.S. Cl. 257/40; 257/59; 438/4; 257/E51.018

(57) ABSTRACT

A structure is disclosed for repairing a defective pixel of an organic light emitting display device of which a defect pixel is repaired. An organic light emitting diode includes a first electrode, a light emitting layer formed on a light emitting region of the first electrode, and a second electrode formed on the light emitting layer. The first electrode and the second electrode are conductively coupled to each other for preventing the organic light emitting diode from emitting light, for example, by irradiating a laser on a portion of the second electrode to cause a short-circuit between the first electrode and the second electrode.

### CROSS-REFERENCE TO RELATED APPLICATIONS

This application claims priority to and the benefit of Korean Patent Application No. 10-2009-0012311, filed on Feb. 16, 2009, in the Korean Intellectual Property Office, the entire content of which is incorporated herein by reference.

### BACKGROUND

1. Field of the Invention

The present invention relates to a structure for repairing a pixel of an organic light emitting display device and a method of repairing the same, and more particularly, to a structure for repairing a defective pixel of an organic light emitting display device and a method of repairing the same.

2. Discussion of Related Art

An organic light emitting display device, which is a type of flat panel display device that displays images using self-luminescent organic light emitting diodes, has excellent brightness and color purity so that it is spotlighted as a next generation display device.

The organic light emitting diode includes an anode electrode, a cathode electrode and an organic light emitting layer interposed therebetween and emits light with a brightness corresponding to a driving current.

However, in organic light emitting display devices, owing to property variations of components provided in each pixel, or disconnections, short circuits, or the like in pixel circuits, an over-current greater than a normal driving current may flow in some pixels causing pixel defects expressed as bright spots. Also, various pixel defects may be formed as stains due to infiltration of foreign material, etc. Such pixel defects cause deterioration of image quality.

### SUMMARY OF THE INVENTION

Therefore, an aspect of the present invention provides a structure for repairing a defective pixel of an organic light emitting display device, and a method of repairing the same.

According to one aspect of the present invention, a structure is disclosed for repairing a pixel of an organic light emitting display device. This structure includes a first electrode coupled to an organic light emitting diode and a second electrode coupled to the organic light emitting diode, wherein the first electrode and the second electrode are conductively coupled to each other for preventing the organic light emitting diode from emitting light.

In some embodiments, the first electrode and the second electrode are coupled to each other through a light emitting layer of the organic light emitting diode in a light emitting region of the first electrode.

In some embodiments, the pixel repair structure of the organic light emitting display device further includes a pixel definition layer that is formed on the first electrode to surround an edge of the first electrode and expose the light emitting region of the first electrode. In these embodiments, the first electrode and the second electrode may be conductively coupled to each other through the pixel definition layer in a region outside the light emitting region, where the first electrode overlaps the second electrode.

The structure for repairing the pixel of the organic light emitting display device may further include a thin film transistor that is formed under the first electrode, having one electrode coupled to the first electrode. An insulating film may be positioned between the thin film transistor and the first electrode, wherein the one electrode of the thin film transistor and the second electrode are conductively coupled to each other through the insulating film.

Also, the one electrode of the thin film transistor may include a repair pattern extending outside of the first electrode.

Here, the repair pattern of the one electrode of the thin film transistor may be conductively coupled to the second electrode through the insulating film.

The pixel repair structure of the organic light emitting display device may further comprise a bus line overlapping the repair pattern of the one electrode of the thin film transistor, the bus line being coupled to the second electrode.

Here, the repair pattern of the one electrode of the thin film transistor and the bus line may be conductively coupled to each other through the insulating film in an overlapping region.

According to another aspect of the present invention, a method of repairing a defective pixel of an organic light emitting display device is provided. The defective pixel of the organic light emitting display device includes an organic light emitting diode including a first electrode, a second electrode, and a light emitting layer between the first electrode and the second electrode. The method includes irradiating a laser to a portion of the defective pixel to conductively couple the first electrode to the second electrode to darken the defective pixel.

In some embodiments, the laser is irradiated to a portion of a light emitting region of the defective pixel in order to damage the light emitting layer so that the first electrode and the second electrode are conductively coupled to each other in the light emitting region, the light emitting region being where the first electrode and the second electrode overlap each other with the light emitting layer interposed therebetween.

In some other embodiments, the laser is irradiated to a portion of a non-light emitting region of the defective pixel so that the first electrode and the second electrode are conductively coupled to each other in the non-light emitting region, the non-light emitting region being where the first electrode and the second electrode overlap each other without the light emitting layer interposed therebetween.

The pixel may further include a thin film transistor disposed under the first electrode, the thin film transistor having one electrode coupled to the first electrode. In some of these embodiments, the laser is irradiated to an upper portion of the one electrode of the thin film transistor to damage a film between the second electrode and the one electrode of the thin film transistor so that the second electrode is conductively coupled to the one electrode of the thin film transistor.

In some other embodiments, the defective pixel further includes a thin film transistor disposed under the first electrode, the thin film transistor having one electrode coupled to the first electrode, the one electrode of the thin film transistor including a repair pattern extending outside of the first electrode.

In these embodiments, the laser is irradiated to the second electrode on the repair pattern so that the repair pattern and the second electrode are conductively coupled to each other.

Some embodiments further include a bus line that is formed in a same layer as the first electrode to overlap with the repair pattern, the bus line being coupled to the second electrode. In these embodiments, the laser is irradiated to a region where the bus line and the repair pattern overlap each other so that the repair pattern and the bus line may be conductively coupled to each other.

In one aspect, the present invention provides a method of repairing a defective pixel by locally irradiating a laser, without entirely removing a light emitting layer of the defective pixel, so that the first electrode and the second electrode of the organic light emitting diode are short-circuited, thus darkening the organic light emitting diode. In another aspect, the present invention provides a structure for a repairing a defective pixel and to facilitate short circuiting the first electrode and the second electrode of the organic light emitting diode.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a plan view showing a pixel of an organic light emitting display device according to one embodiment of the present invention;

FIG. 2 is a cross-sectional view taken along line I-I′ of FIG. 1;

FIG. 3 is a plan view showing a pixel of an organic light emitting display device according to another embodiment of the present invention; and

FIG. 4 is a plan view showing a pixel of an organic light emitting display device according to still another embodiment of the present invention.

### DETAILED DESCRIPTION OF EXEMPLARY EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements.

Hereinafter, exemplary embodiments according to the present invention will be described in detail with reference to the accompanying drawings.

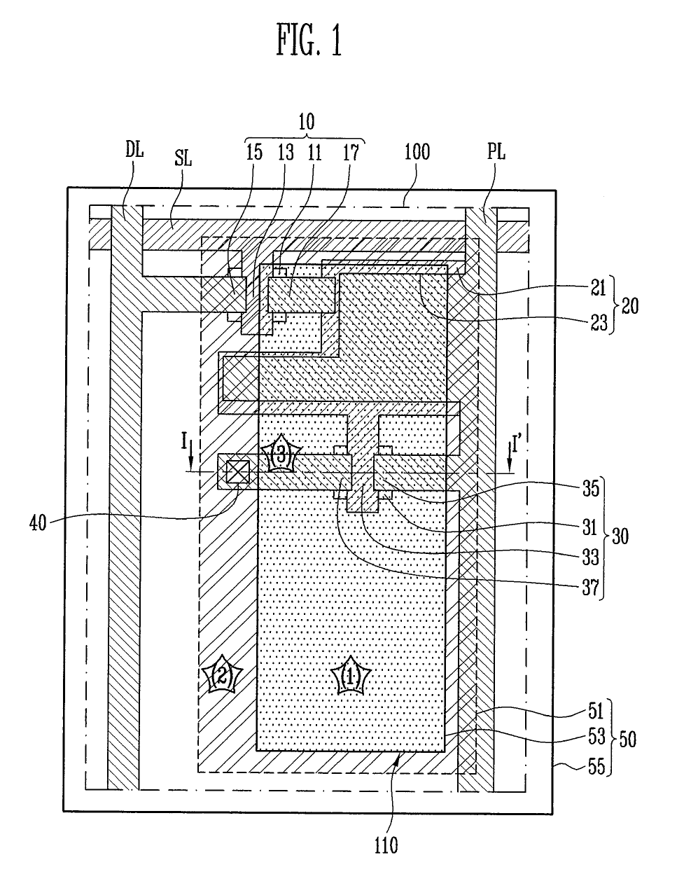

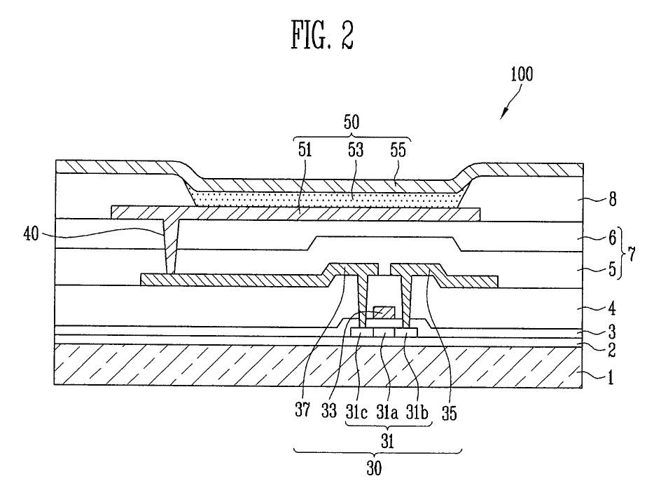

FIG. 1 is a plan view showing a pixel of an organic light emitting display device according to an embodiment of the present invention, a structure of repairing the same, and a method of repairing the same, and FIG. 2 is a cross-sectional view taken along the line I-I′ of FIG. 1.

In FIGS. 1 and 2, one embodiment of the present invention will be explained with reference to a pixel having a relatively simple structure in order to clearly explain aspects of one embodiment of the present invention. However, the present invention is not limited to the pixel having the structure as shown in FIGS. 1 and 2, but it may also be applied to pixels having various structures.

First, referring to FIG. 1, the pixel 100 of the organic light emitting display device according to one embodiment of the present invention includes a first transistor 10, a storage capacitor 20, a second transistor 30, and an organic light emitting diode 50.

The first transistor 10 includes a semiconductor layer 11, a gate electrode 13 overlapping with a channel region of the semiconductor layer 11, and a source electrode 15 and a drain electrode 17 that are coupled (e.g., electrically or conductively coupled) to a source region and a drain region of the semiconductor layer 11, respectively.

Here, the first transistor 10 is a switching transistor. The gate electrode 13 of the first transistor 10 is coupled to a scan line SL, and the source electrode and drain electrode 15 and 17 are coupled to a data line DL and one electrode of the storage capacitor 20, respectively.

The first transistor 10 transfers a data signal supplied from the data line DL to the storage capacitor 20 corresponding to a scan signal supplied from the scan line SL.

The storage capacitor 20 includes first and second electrodes 21 and 23 with an insulating layer (not shown) interposed therebetween. The storage capacitor 20 stores a data signal supplied via the first transistor 10 and maintains it for one frame.

The second transistor 30 includes a semiconductor layer 31, a gate electrode 33 overlapping with a channel region of the semiconductor layer 31, and a source electrode 35 and a drain electrode 37 that are coupled to a source region and a drain region of the semiconductor layer 31, respectively.

Here, the second transistor 30 is a driving transistor. The gate electrode 33 of the second transistor 30 is coupled to the first electrode 21 of the storage capacitor 20, and the source electrode 35 thereof is coupled to the second electrode 23 of the storage capacitor 20 and a first power source line PL.

In other words, the storage capacitor 20 is coupled between the gate electrode 33 and the source electrode 35 of the second transistor 30, and thus, a voltage Vgs between the gate electrode 33 and the source electrode 35 of the second transistor 30 is maintained by the storage capacitor 20.

The drain electrode 37 of the second transistor 30 is coupled to a first electrode 51 of the organic light emitting diode through a contact hole 40 (or a via hole).

The second transistor 30 supplies current to the organic light emitting diode 50, the current having a magnitude corresponding to a voltage (data voltage) charged in the storage capacitor 20.

Although an embodiment of the present invention is explained assuming that the first transistor 10, the storage capacitor 20, and the second transistor 30 are provided in the pixel 100 as the driving circuitry that drives the organic light emitting layer, this is merely one embodiment, and the present invention is not limited thereto. In other words, in some embodiments, at least one constituent, for example, all the constituents that constitute the driver may also be provided outside the panel. In this case, the source/drain wires coupled to the driver are formed inside the panel so that they may also be coupled to the organic light emitting diode 50.

Also, in the aforementioned description, the source electrodes 15 and 35 and the drain electrodes 17 and 37 of the first and second transistors 10 and 30 have been separately explained in order to clarify the present embodiment. However, in other embodiments the source electrodes 15 and 35 and the drain electrodes 17 and 37 may also be varied according to the circuit constitution or the type of transistor.

The organic light emitting diode 50 includes a first electrode 51 coupled to one electrode (e.g., the drain electrode 37) of the second transistor 30 and an organic light emitting layer 53 and a second electrode 55, which are sequentially stacked on the first electrode 51. In various embodiments, the first electrode 51 of the organic light emitting diode 50 may be set as an anode electrode or a cathode electrode, and the second electrode 55 may be set as an electrode different from the first electrode 51.

For convenience, the first electrode 51 and the second electrode 55 of the organic light emitting diode are referred to as the anode electrode and the cathode electrode, respectively. However, the present invention is not limited thereto, and the first electrode 51 and the second electrode 55 of the organic light emitting diode may also be implemented as the cathode electrode and the anode electrode, respectively.

The organic light emitting diode 50 emits light with a brightness corresponding to a current supplied from the second transistor 30.

Here, the anode electrode 51 is formed on the first and second transistors 10 and 30 and the storage capacitor 20 to overlap therewith. However, the anode electrode 51 in other embodiments may be disposed not to overlap with the region where they are formed depending on an emission direction of a pixel, etc.

The pixel definition layer 8 in FIG. 2 and the light emitting layer 53 are formed on the anode electrode 51. The pixel definition layer is formed to surround an edge of the anode electrode 51 to expose a portion of the anode electrode 51 in the light emitting region 110 and the light emitting layer 53 being formed at least on the anode electrode 51 in the light emitting region 110. In some embodiments, the pixel definition layer 8 may be omitted, and the light emitting layer 53 may be patterned on the anode electrode 51.

The cathode electrode 55 is formed on the light emitting layer 53. The cathode electrode 55 may be formed overall on the pixel unit on which the pixels 100 are formed.

Hereinafter, a structure of the pixel 100 according to one embodiment will be described in detail with reference to FIG. 2. For convenience, the organic light emitting diode 50 and the second transistor 30 coupled to the organic light emitting diode 50 is shown in FIG. 2.

However, according to the structure of the pixel, in other embodiments the second transistor 30 may not be directly coupled to the organic light emitting diode 50 but an emission control transistor (not shown) may be coupled therebetween. In this case, the transistor coupled directly to the organic light emitting diode 50 may be the emission control transistor that controls a current supply to the organic light emitting diode 50 by an emission control line. Therefore, the second transistor 30 will be referred to as a thin film transistor 30 hereinafter.

Referring to FIG. 2, the thin film transistor 30 is formed on a buffer layer 2 on the substrate 1, and an insulating film 7 that includes a passivation layer 5 and/or a planarization film 6 is formed on the thin film transistor 30. The organic light emitting diode 50, which is coupled to the thin film transistor 30 through a contact hole 40 formed through the insulating film 7, is formed on the insulating film 7.

More specifically, the thin film transistor 30 includes the semiconductor layer 31 that is formed on the buffer layer 2 and includes the channel region 31a and source and drain regions 31b and 31c; the gate electrode 33 that is formed on the semiconductor layer 31 to overlap with at least the channel region 31a with a gate insulating film 3 interposed therebetween; and the source and drain electrodes 35 and 37 that are formed on the gate electrode 33, with an interlayer insulating film 4 interposed therebetween, and are coupled to the source and drain regions 31b and 31c, respectively.

The organic light emitting diode 50 includes the anode electrode 51 that is formed on the thin film transistor 30 with the insulating film 7 interposed therebetween, and is coupled to one electrode of the thin film transistor 30, e.g., the drain electrode 37, through the contact hole 40; the organic light emitting layer 53 that is formed on the anode electrode 51 in the light emitting region 110 not covered by the pixel definition layer 8; and the cathode electrode 55 that is formed overall on the light emitting layer 53 and the pixel definition layer 8.

However, when a defective pixel, for example expressed as a bright spot, occurs on the pixel 100 in FIGS. 1 and 2 as described above, a laser is selectively irradiated to a portion of the pixel 100 to couple (e.g., to electrically or conductively couple) the anode electrode 51 to the cathode electrode 55. Accordingly, the pixel 100 is easily darkened to repair the pixel defect without removing the entire light emitting layer 53. A dark spot is weakly perceived by a viewer's eyes compared to bright spots or stains, etc., so that when a pixel defect occurs, the pixel defect can be repaired by darkening the defective pixel.

In other words, if a defect of the pixel 100 is repaired as disclosed above, there is provided a structure for repairing a pixel in which the anode electrode 51 is conductively coupled to the cathode electrode 51 not to emit light. Here, the pixel repairing structure refers to a repairing structure in which when a pixel defect (e.g., a pixel defect other than a dark spot defect) occurs from at least one pixel of a plurality of pixels of the organic light emitting display device, the defective pixel is repaired according to an aspect of the present invention. In other words, the pixel repairing structure refers to a pixel structure after the defective pixel is repaired by an embodiment of the present invention to be darkened.

A region to which the laser is selectively irradiated may be a portion of the light emitting region 110, e.g., Region (1) in FIG. 1. However, a wavelength range of the laser used in shorting (e.g., electrically or conductively coupling) the anode electrode 51 and the cathode electrode 55 may be set as a wavelength range that is easily absorbed by a layer to be shorted or a wavelength range that heat is generated to the extent that the light emitting layer 53 interposed between the anode electrode 51 and the cathode electrode 55 is damaged.

As described above, the anode electrode 51 is coupled to the cathode electrode 55 by selectively irradiating a laser to a portion of the light emitting region 110, which leads to form the pixel repairing structure in which, in one embodiment, the anode electrode 51 electrically or conductively contacts the cathode electrode 55 by passing through the light emitting layer 53 in the light emitting region 110 to be coupled to each other.

In some embodiments the region to which the laser is irradiated is a region other than the light emitting region 110. For example, the anode electrode 51 can be coupled to the cathode electrode 55 by selectively irradiating a laser to Region (2) in FIG. 1, that is, an outer region of the light emitting region 110 where edge of the anode electrode 51 covered by the pixel definition layer 8 overlaps with the cathode electrode 55.

In this case, the pixel definition layer 8, rather than the light emitting layer 53, may be interposed between the anode electrode 51 and the cathode electrode 55 in the region to which the laser is irradiated, thus obtaining the pixel repairing structure in which the anode electrode 51 and the cathode electrode 55 can be coupled through the pixel definition layer 8.

In some embodiments, an intermediate film (e.g., the insulating film 7) between the drain electrode 37 and the cathode electrode 55 is damaged by irradiating a laser having larger energy to the upper portion of the drain electrode 37 of the thin film transistor as shown in Region (3) in FIG. 1, making it possible to couple the drain electrode 37 to the cathode electrode 55. Because the drain electrode 37 is coupled to the anode electrode 51 through the contact hole 40, the anode electrode 51 is coupled to the cathode electrode 55 in the end.

In this case, the pixel 100 of which a defect is repaired has the pixel repairing structure in which an electrode (for example, the drain electrode 37) of the thin film transistor 30 is coupled to the cathode electrode 55 through the insulating film 7.

In a further embodiment, when the laser is irradiated so that one electrode of the thin film transistor 30 is coupled to the cathode electrode 55, the one electrode of the thin film transistor 30 is formed having a greater thickness compared to the anode electrode 51, etc., thereby improving the stability of the short. In other words, when one electrode of the thin film transistor 30 has a relatively large thickness, there is a significant reduction to the probability that the short is not formed while the portion irradiated with the laser is removed, thereby improving the stability of the short.

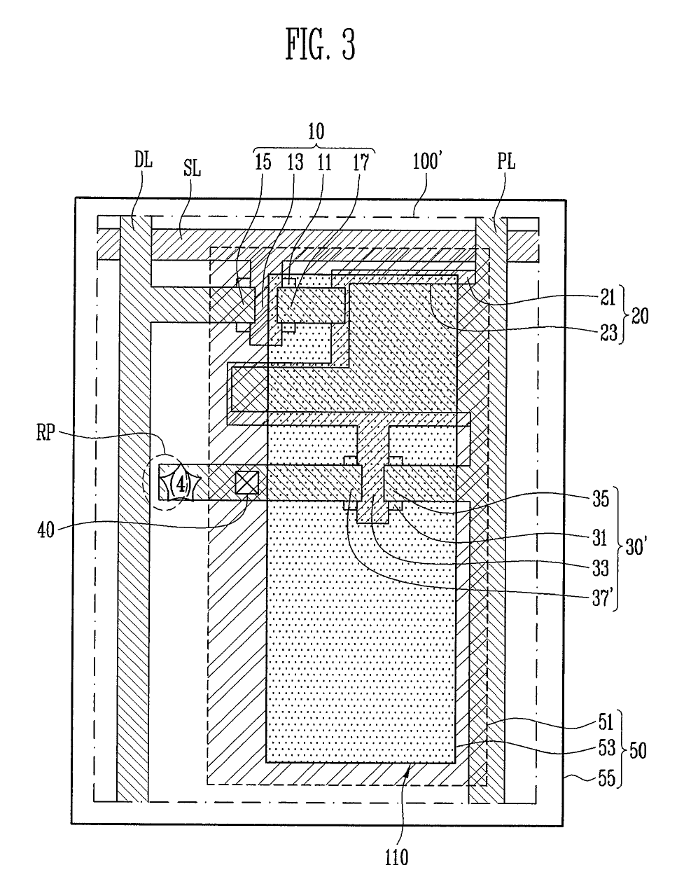

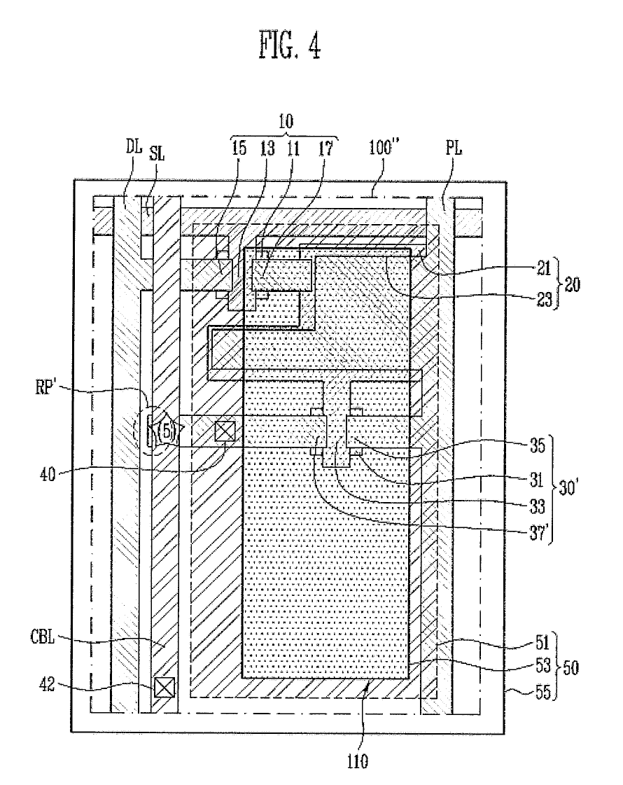

FIG. 3 is a plan view showing a pixel of an organic light emitting display device according to another embodiment of the present invention, a structure of repairing the same to repair a defective pixel, and a method of repairing the same. FIG. 4 is a plan view showing a pixel of an organic light emitting display device according to still another embodiment of the present invention, a structure of repairing the same to repair a defective pixel, a method of repairing the same.

In FIGS. 3 and 4, the same parts as those in FIG. 1 will be given with the same reference numerals and the detailed description thereof will be omitted.

First, referring to FIG. 3, a pixel 100′ may further include a repair pattern RP that can be used to short-circuit a drain electrode 37′ of a thin film transistor 30′ to a cathode electrode 55 in a region not overlapping an anode electrode 51.

The repair pattern RP is a pattern in which the drain electrode 37′ of the thin film transistor 30′ is extended to an outer region of the anode electrode 51 so that it extends to the region not overlapping the anode electrode 51, such as region (4) in FIG. 3. As a laser is irradiated to the cathode electrode 55 on the repair pattern RP, the drain electrode 37′ can be easily short-circuited from the cathode electrode 55 through the repair pattern RP.

In this case, the pixel 100′ of which a defect is repaired has the pixel repairing structure in which the repair pattern RP where one electrode of the thin film transistor 30′ is extended and the cathode electrode 55 are coupled to each other through an insulating film 7 and/or a pixel definition layer 8. Here, the insulating film 7 and/or the pixel definition layer 8 may also have a shape in which non-critical portions are removed in order to make the repair easy.

In another exemplary embodiment as shown in FIG. 4, a cathode bus line CBL that is coupled to the cathode electrode 55 in order to reduce a voltage drop IR Drop in the cathode electrode 55 is further included. For example, the cathode bus line CBL is disposed on the same layer, having the same material as the anode electrode 51, but is spaced from the anode electrode 51 to be insulated. The cathode bus line CBL may be coupled to the cathode electrode 55 through a contact hole 42.

When the cathode bus line CBL is provided as described above, the repair pattern RP and the cathode bus line CBL overlap with each other as shown in region (5) in FIG. 4, wherein the repair pattern RP′ can be coupled electrically to the cathode bus line CBL by irradiating a laser to the overlapped region.

In this case, the pixel 100″ of which a defect is repaired has a pixel repairing structure in which the repair pattern RP′ and the cathode bus line CBL are coupled to each other through the insulating film 7.

As shown in FIGS. 3 and 4, when the separate repair pattern RP or RP′ is formed on the outer regions of the pixels 100′ and 100″, it can prevent another defect due to the damage of the lower film in the pixels 100′ and 100″ from being generated.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A structure for repairing a pixel comprising an organic emitting diode of an organic light emitting display device, comprising:
a first electrode coupled to the organic light emitting diode; and
a second electrode coupled to the organic light emitting diode,
wherein the first electrode and the second electrode are coupled to each other through a laser irradiation to prevent the organic light emitting diode from emitting light.

2. The structure for repairing the pixel of the organic light emitting display device as claimed in claim 1, wherein the first electrode and the second electrode are coupled to each other through a light emitting layer of the organic light emitting diode in a light emitting region of the first electrode.

3. The structure for repairing the pixel of the organic light emitting display device as claimed in claim 1, further comprising:
a pixel definition layer on the first electrode to surround an edge of the first electrode and expose a light emitting region of the first electrode,
wherein the first electrode and the second electrode are coupled to each other through the pixel definition layer in a region outside the light emitting region, where the first electrode overlaps the second electrode.

4. The structure for repairing the pixel of the organic light emitting display device as claimed in claim 1, further comprising:
a thin film transistor under the first electrode, having one electrode coupled to the first electrode; and
an insulating film between the thin film transistor and the first electrode,
wherein the one electrode of the thin film transistor and the second electrode are coupled to each other through the insulating film.

5. The structure for repairing the pixel of the organic light emitting display device as claimed in claim 4, wherein the one electrode of the thin film transistor comprises a repair pattern extending beyond a boundary of the first electrode.

6. The structure for repairing the pixel of the organic light emitting display device as claimed in claim 5, wherein the repair pattern of the one electrode of the thin film transistor is coupled to the second electrode through the insulating film.

7. The structure for repairing the pixel of the organic light emitting display device as claimed in claim 5, further comprising:
a bus line overlapping the repair pattern of the one electrode of the thin film transistor, the bus line being coupled to the second electrode.

8. The structure for repairing the pixel of the organic light emitting display device as claimed in claim 7, wherein the repair pattern of the one electrode of the thin film transistor and the bus line are coupled to each other through the insulating film in an overlapping region.

9. The structure for repairing the pixel of the organic light emitting display device as claimed in claim 4, wherein the one electrode of the thin film transistor is a drain electrode.

10. The structure for repairing the pixel of the organic light emitting display device as claimed in claim 4, wherein the one electrode of the thin film transistor has a greater thickness than that of the second electrode.

11. A method of repairing a defective pixel of an organic light emitting display device, the defective pixel of the organic light emitting display device comprising an organic light emitting diode comprising a first electrode, a second electrode, and a light emitting layer between the first electrode and the second electrode, the method comprising:
irradiating a laser to a portion of the defective pixel to conductively couple the first electrode to the second electrode to darken the defective pixel.

12. The method of repairing the defective pixel of the organic light emitting display device as claimed in claim 11, wherein the irradiating of the laser comprises irradiating the laser to a portion of a light emitting region of the defective pixel in order to damage the light emitting layer so that the first electrode and the second electrode are coupled to each other in the light emitting region, the light emitting region being where the first electrode and the second electrode overlap each other with the light emitting layer therebetween.

13. The method of repairing the defective pixel of the organic light emitting display device as claimed in claim 11, wherein the irradiating of the laser comprises irradiating the laser to a portion of a non-light emitting region of the defective pixel so that the first electrode and the second electrode are conductively coupled to each other in the non-light emitting region, the non-light emitting region being where the first electrode and the second electrode overlap each other without the light emitting layer therebetween.

14. The method of repairing the defective pixel of the organic light emitting display device as claimed in claim 11, wherein the defective pixel further comprises a thin film transistor under the first electrode, the thin film transistor having one electrode electrically coupled to the first electrode,
wherein the irradiating of the laser comprises irradiating the laser on an upper portion of the one electrode of the thin film transistor to damage a film between the second electrode and the one electrode of the thin film transistor so that the second electrode is coupled to the one electrode of the thin film transistor.

15. The method of repairing the defective pixel of the organic light emitting display device as claimed in claim 11, wherein the defective pixel further comprises a thin film transistor under the first electrode, the thin film transistor having one electrode electrically coupled to the first electrode, the one electrode of the thin film transistor comprising a repair pattern extending beyond a boundary of the first electrode.

16. The method of repairing the defective pixel of the organic light emitting display device as claimed in claim 15, wherein the irradiating of the laser comprises irradiating the laser on the second electrode on the repair pattern so that the repair pattern and the second electrode are conductively coupled to each other.

17. The method of repairing the defective pixel of the organic light emitting display device as claimed in claim 15, wherein a bus line in a same layer as the first electrode overlaps with the repair pattern, the bus line being coupled to the second electrode, wherein the irradiating of the laser comprises irradiating the laser on a region where the bus line and the repair pattern overlap each other so that the repair pattern and the bus line are conductively coupled to each other.
